(19) United States
(12) Patent Application Publication
(10) Pub. No.: US 2023/0301097 A1
(43) Pub. Date: Sep. 21, 2023

(54) SEMICONDUCTOR MEMORY DEVICE

(71) Applicant: SK hynix Inc., Icheon-si Gyeonggi-do (KR)

(72) Inventor: Sang Hyon KWAK, Icheon-si Gyeonggi-do (KR)

(73) Assignee: SK hynix Inc., Icheon-si Gyeonggi-do (KR)

(21) Appl. No.: 17/949,485

(22) Filed: Sep. 21, 2022

(30) Foreign Application Priority Data
Mar. 18, 2022 (KR) 10-2022-0034262

(51) Int. Cl. H01L 27/11582; H01L 27/11565; H01L 23/528

(52) U.S. Cl. CPC H01L 27/11582; H01L 27/11565; H01L 23/5283

(57) ABSTRACT

A semiconductor memory device is provided. The semiconductor memory device includes a source structure, a first drain select line spaced apart from the source structure, first to fourth bit lines of a first group of bit lines spaced apart from the first drain select line, first to fourth channel structures of a first column of channel structures extending from the source structure to pass through the first drain select line, and first to fourth contact plugs of the first contact group of contact plugs connecting the first to fourth channel structures of the first column of channel structures to the first to fourth bit lines of the first group of bit lines, respectively, and in which each of the first to fourth channel structures of the first column of channel structures extend to overlap the first to fourth bit lines of the first group of bit lines.

### CROSS-REFERENCE TO RELATED APPLICATION

The present application claims priority under 35 U.S.C. § 119(a) to Korean patent application number 10-2022-0034262 filed on Mar. 18, 2022, in the Korean Intellectual Property Office, the entire disclosure of which is incorporated by reference herein.

### BACKGROUND

### 1. Technical Field

Various embodiments of the present disclosure generally relate to a semiconductor memory device, and more particularly, to a three-dimensional semiconductor memory device.

### 2. Related Art

In order to improve an integration degree of a semiconductor memory device, a three-dimensional semiconductor memory device has been proposed. The three-dimensional semiconductor memory device may include a memory cell string defined along a channel structure. In the three-dimensional semiconductor memory device, a plurality of channel structures may pass through a plurality of conductive patterns stacked apart from each other on a substrate. The plurality of conductive patterns may be provided to access a memory cell string.

By increasing the number of stacks of the plurality of conductive patterns described above, the integration degree of the three-dimensional semiconductor memory device may be improved, but stability of a manufacturing process may deteriorate.

### SUMMARY

According to an embodiment of the present disclosure, a semiconductor memory device may include a source structure having a surface extending in a first direction and a second direction different from the first direction, a first drain select line spaced apart from the source structure in a third direction, the third direction crossing the surface of the source structure, a first group of bit lines including first, second, third, and fourth bit lines, wherein the first group of bit lines is spaced apart from the first drain select line in the third direction, wherein the first to fourth bit lines of the first group of bit lines extend in the first direction, and wherein the first to fourth bit lines of the first group of bit lines are spaced apart from each other in the second direction, a first column of channel structures including first, second, third, and fourth channel structures, wherein the first to fourth channel structures of the first column of channel structures are spaced apart from each other in the first direction, and wherein the first to fourth channel structures of the first column of channel structures, each extend from the source structure in the third direction to pass through the first drain select line, a first contact group of contact plugs including first, second, third, and fourth contact plugs, wherein the first to fourth contact plugs of the first contact group of contact plugs connect the first to fourth channel structures of the first column of channel structures to the first to fourth bit lines of the first group of bit lines, respectively, and a word line disposed between the first drain select line and the source structure and surrounding the first to fourth channel structures of the first column of channel structures. Each of the first to fourth channel structures of the first column of channel structures may extend in the second direction to overlap the first to fourth bit lines of the first group of bit lines.

According to an embodiment of the present disclosure, a semiconductor memory device may include a source structure having a surface extending in a first direction and a second direction different from the first direction, a word line disposed to be spaced apart from the source structure in a third direction crossing the surface of the source structure, an insulating structure overlapping the word line, the insulating structure extending in the second direction, a first drain select line and a second drain select line spaced apart from the word line in the third direction, the first drain select line and the second drain select line spaced apart from each other in the first direction with the insulating structure interposed therebetween, a first column of channel structures including first, second, third, fourth, fifth, sixth, seventh, and eighth channel structures, wherein the first to eighth channel structures of the first column of channel structures are spaced apart from each other along the first direction, wherein each of the first to eighth channel structures of the first column of channel structures extend from the source structure in the third direction, wherein each of the first to fourth channel structures of the first column of channel structures pass through the word line and the first drain select line, and wherein each of the fifth to eighth channel structures of the first column of channel structures pass through the word line and the second drain select line, a first group of bit lines including first, second, third, and fourth bit lines, wherein the first to fourth bit lines of the first group of bit lines are spaced apart from each other in the second direction, and wherein the first to fourth bit lines of the first group of bit lines extend in the first direction to overlap the first to eighth channel structures of the first column, a first contact group of contact plugs including first, second, third, fourth, fifth, sixth, seventh, and eighth contact plugs, wherein the first to fourth contact plugs of the first contact group of contact plugs connect the first to fourth channel structures of the first column of channel structures to the first to fourth bit lines of the first group of bit lines, respectively, and wherein the fifth to eighth contact plugs of the first contact group of contact plugs connect the fifth to eighth channel structures of the first column of channel structures to the first to fourth bit lines of the first group of bit lines, respectively.

### BRIEF DESCRIPTION OF THE DRAWINGS

FIG. 1 is a block diagram illustrating a semiconductor memory device according to an embodiment of the present disclosure.

FIG. 2 is a circuit diagram illustrating a memory cell string according to an embodiment of the present disclosure.

FIGS. 3A and 3B are diagrams schematically illustrating an arrangement of a peripheral circuit structure, a memory cell array, a plurality of bit lines, and a source structure according to embodiments of the present disclosure.

FIG. 4 is a plan view illustrating a semiconductor memory device according to an embodiment of the present disclosure.

FIG. 5 illustrates a cross-sectional view of the semiconductor memory device taken along a line I-I′ and a line II-II′ shown in FIG. 4.

FIG. 6 is a cross-sectional view illustrating a source structure and a channel structure according to an embodiment of the present disclosure.

FIG. 7 is an enlarged plan view of a portion of the semiconductor memory device shown in FIG. 4.

FIG. 8 is a perspective view illustrating a portion of the semiconductor memory device shown in FIG. 4.

FIG. 9 is a plan view illustrating a method of manufacturing a semiconductor memory device according to an embodiment of the present disclosure.

FIGS. 10A, 10B, 10C, 10D, and 10E are perspective views illustrating a method of manufacturing a semiconductor memory device according to an embodiment of the present disclosure.

FIG. 11 is a block diagram illustrating a configuration of a memory system according to an embodiment of the present disclosure.

FIG. 12 is a block diagram illustrating a configuration of a computing system according to an embodiment of the present disclosure.

### DETAILED DESCRIPTION

Specific structural and functional descriptions disclosed herein are merely illustrative for the purpose of describing embodiments according to the concept of the present disclosure. Embodiments according to the concept of the present disclosure can be implemented in various forms, and they should not be construed as being limited to the specific embodiments set forth herein.

It will be understood that, although the terms “first”, “second”, etc. may be used herein to describe various elements, these elements are not limited by these terms. These terms are used for distinguishing one element from another element and not to suggest a number or order of elements.

An embodiment of the present disclosure may provide a semiconductor memory device capable of improving stability of a manufacturing process.

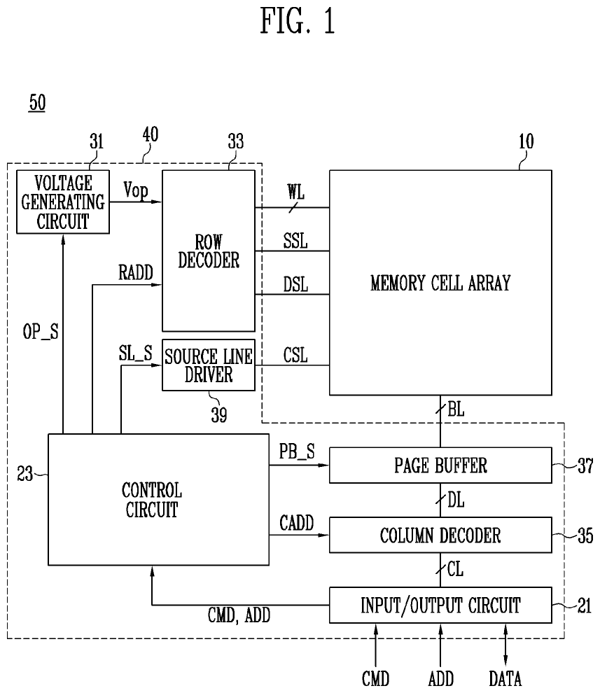

FIG. 1 is a block diagram illustrating a semiconductor memory device according to an embodiment of the present disclosure.

Referring to FIG. 1, the semiconductor memory device 50 includes a peripheral circuit structure 40 and a memory cell array 10.

The peripheral circuit structure 40 may be configured to perform a program operation for storing data in the memory cell array 10, a read operation for outputting data stored in the memory cell array 10, and an erase operation for erasing data stored in the memory cell array 10. As an embodiment, the peripheral circuit structure 40 may include an input/output circuit 21, a control circuit 23, a voltage generating circuit 31, a row decoder 33, a column decoder 35, a page buffer 37, and a source line driver 39.

The memory cell array 10 may include a plurality of memory cell strings. The plurality of memory cell strings of the memory cell array 10 may be connected to a common source line CSL in parallel. The plurality of memory cell strings may be connected to a plurality of bit lines BL. Each memory cell string may be connected to a drain select line DSL, a plurality of word lines WL, and a source select line SSL.

The input/output circuit 21 may transmit a command CMD and an address ADD received from an external device (for example, a memory controller) of the semiconductor memory device 50 to the control circuit 23. The input/output circuit 21 may exchange data DATA with the external device and the column decoder 35.

The control circuit 23 may output an operation signal OP_S, a row address RADD, a source line control signal SL_S, a page buffer control signal PB_S, and a column address CADD in response to the command CMD and the address ADD.

The voltage generating circuit 31 may generate various operation voltages Vop used for the program operation, the read operation, and the erase operation in response to the operation signal OP_S.

The row decoder 33 may transmit the operation voltages Vop to the drain select line DSL, the word line WL, and the source select line SSL in response to the row address RADD.

The column decoder 35 may transmit the data DATA input from the input/output circuit 21 to the page buffer 37 or transmit the data DATA stored in the page buffer 37 to the input/output circuit 21, in response to the column address CADD. The column decoder 35 may exchange the data DATA with the input/output circuit 21 through a column line CL. The column decoder 35 may exchange the data DATA with the page buffer 37 through a data line DL.

The page buffer 37 may temporarily store the data DATA received through the bit line BL in response to the page buffer control signal PB_S. The page buffer 37 may sense a voltage or a current of the bit line BL during the read operation.

The source line driver 39 may control a voltage applied to the common source line CSL in response to the source line control signal SL_S.

In order to improve an integration degree of the semiconductor memory device, in an embodiment, the memory cell array 10 may overlap the peripheral circuit structure 40.

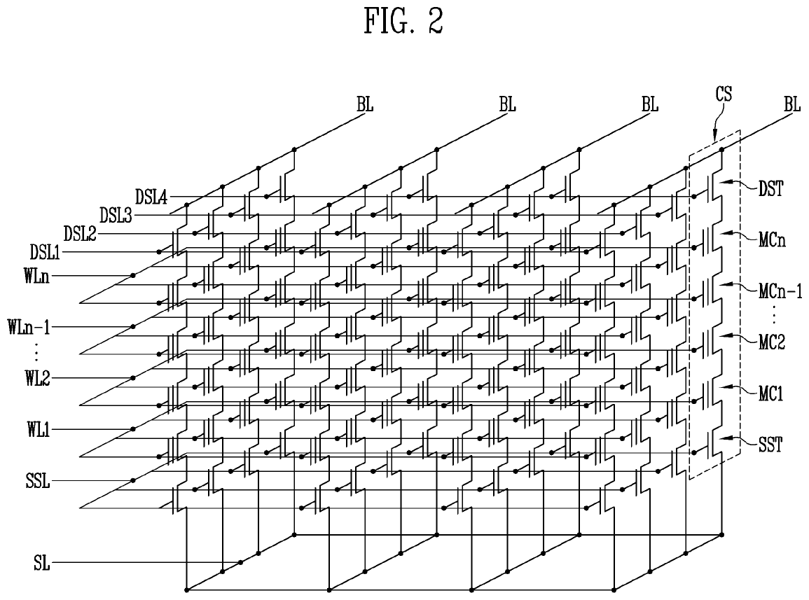

FIG. 2 is a circuit diagram illustrating a memory cell string according to an embodiment of the present disclosure.

Referring to FIG. 2, a plurality of memory cell strings CS may be connected to a source structure SL in parallel. The source structure SL may be connected to the peripheral circuit structure 40 via the common source line CSL shown in FIG. 1. The source structure SL may be connected to a channel structure of the memory cell string CS. As an embodiment, an operation voltage for discharging a potential of the channel structure of the memory cell string CS may be applied to the source structure SL.

The plurality of memory cell strings CS may be connected to the plurality of bit lines BL. The plurality of memory cell strings CS may be divided into a plurality of columns individually controlled by the plurality of bit lines BL. Each bit line BL may be connected to a memory cell string CS of a column corresponding thereto. The bit line BL may be connected to a channel structure of the memory cell string CS corresponding thereto. As an embodiment, an operation voltage for precharging the channel structure of the memory cell string CS may be applied to the bit line BL.

Each memory cell string CS may include at least one source select transistor SST, a plurality of memory cells MC1 to MCn, and at least one drain select transistor DST. The plurality of memory cells MC1 to MCn may be connected in series between the source select transistor SST and the drain select transistor DST. The plurality of memory cells MC1 to MCn may be connected to the source structure SL via the source select transistor SST. The plurality of memory cells MC1 to MCn may be connected to a bit line BL corresponding thereto via the drain select transistor DST.

Each memory cell string CS may be connected to a source select line SSL, a plurality of word lines WL1 to WLn, and a drain select line DSL1, DSL2, DSL3, or DSL4. An operation of the memory cell string CS may be controlled by gate voltages applied to the source select line SSL, the plurality of word lines WL1 to WLn, and the drain select line DSL1, DSL2, DSL3, or DSL4.

The plurality of memory cell strings CS may be connected to each of the plurality of word lines WL1 to WLn. The plurality of memory cell strings CS commonly connected to each of the word lines WL1 to WLn may be individually controlled by drain select lines separated from each other. As an embodiment, a first drain select line DSL1, a second drain select line DSL2, a third drain select line DSL3, and a fourth drain select line DSL4 separated from each other may be individually connected to first to fourth memory cell strings different from each other. Each of the word lines WL1 to WLn may be commonly connected to first to fourth memory cell strings. The first to fourth memory cell strings may be controlled by the same bit line BL. The first to fourth memory cell strings connected to the same bit line BL may be individually controlled by the first to fourth drain select lines DSL1 to DSL4. The source select line SSL may be commonly connected to the first to fourth memory cell strings similar to the plurality of word lines WL1 to WLn. An embodiment of the present disclosure is not limited to that described above, and a connection structure between the first to fourth memory cell strings and the source select line SSL may be various.

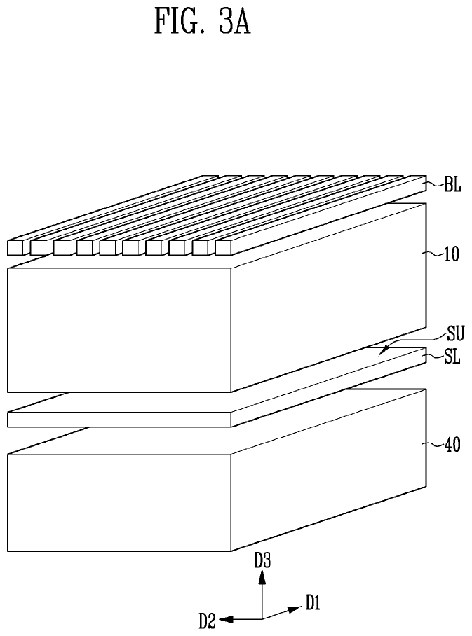

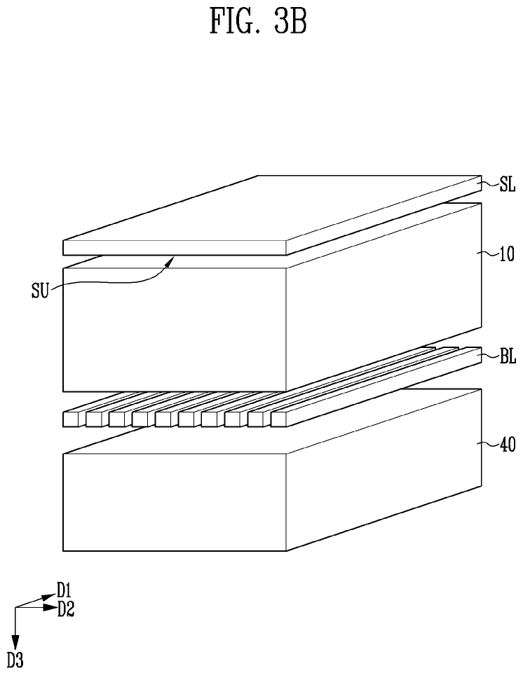

FIGS. 3A and 3B are diagrams schematically illustrating an arrangement of a peripheral circuit structure, a memory cell array, a plurality of bit lines, and a source structure according to embodiments of the present disclosure.

Referring to FIGS. 3A and 3B, the peripheral circuit structure 40 may be disposed on a substrate extending in a first direction D1 and a second direction D2 different from the first direction D1. The first direction D1 and the second direction D2 may be defined as directions in which axes crossing each other face. As an embodiment, the first direction D1 may be an X-axis direction of an XYZ coordinate system, and the second direction D2 may be a Y-axis direction of the XYZ coordinate system.

The source structure SL, the memory cell array 10, and the plurality of bit lines BL may overlap the peripheral circuit structure 40. The memory cell array 10 may be disposed between the source structure SL and the plurality of bit lines BL. The source structure SL may have a surface SU facing the memory cell array 10. The surface of the source structure SL may extend in the first direction D1 and the second direction D2.

The memory cell array 10 and the plurality of bit lines BL may be disposed in a third direction D3 crossing the surface SU of the source structure SL. As an embodiment, the third direction D3 may be a direction in which a Z-axis of the XYZ coordinate system faces.

The memory cell array 10 may overlap the peripheral circuit structure 40, and configurations between the memory cell array 10 and the peripheral circuit structure 40 may be various. As an embodiment, as shown in FIG. 3A, the memory cell array 10 may overlap the peripheral circuit structure 40 with the source structure SL interposed therebetween. In this case, an interconnection (not shown) may be disposed between the peripheral circuit structure 40 and the source structure SL. As an embodiment, as shown in FIG. 3B, the memory cell array 10 may overlap the peripheral circuit structure 40 with the plurality of bit lines BL interposed therebetween. In this case, an interconnection (not shown) may be disposed between the peripheral circuit structure 40 and the plurality of bit lines BL.

Although not shown in the drawing, the interconnection described with reference to FIGS. 3A and 3B may include a plurality of conductive patterns for electrically connecting the peripheral circuit structure 40 to the memory cell array 10, the plurality of bit lines BL, and the source structure SL.

A process of forming the peripheral circuit structure 40, the memory cell array 10, the plurality of bit lines BL, and the source structure SL shown in FIGS. 3A and 3B may be variously performed. Referring to FIG. 3A, as an embodiment, a process for forming the source structure SL, the memory cell array 10, and the plurality of bit lines BL may be performed on the peripheral circuit structure 40. Referring to FIG. 3B, as an embodiment, a process for forming the memory cell array 10 and the plurality of bit lines BL may be performed separately from the process for forming the peripheral circuit structure 40. In this case, the memory cell array 10 and the plurality of bit lines BL may be connected to the peripheral circuit structure 40 by a bonding process, and the source structure SL may be formed after the bonding process.

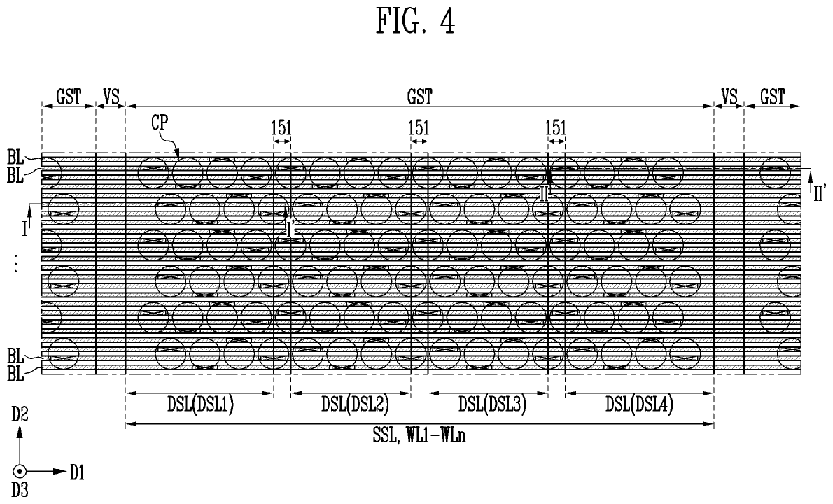

FIG. 4 is a plan view illustrating a semiconductor memory device according to an embodiment of the present disclosure.

Referring to FIG. 4, the memory cell array of the semiconductor memory device may include a plurality of gate stacks GST and a plurality of cell plugs CP passing through each of the gate stacks GST. The plurality of bit lines BL of the semiconductor memory device may overlap the plurality of cell plugs CP. The plurality of cell plugs CP may be connected to the plurality of bit lines BL via the plurality of contact plugs CT.

The plurality of gate stacks GST may be spaced apart from each other in the first direction D1. A vertical structure VS may be disposed between adjacent gate stacks GST. The vertical structure VS may have a width defined along the first direction D1, a length defined along the second direction D2, and a height defined along the third direction D3.

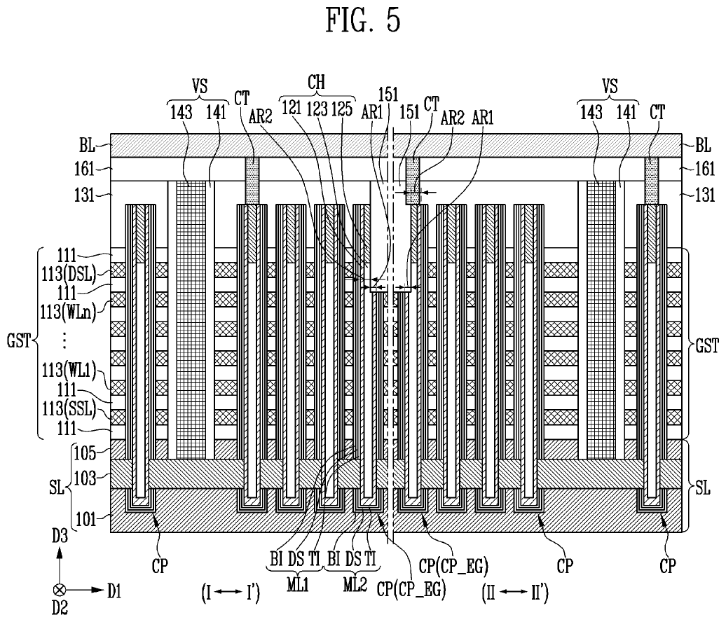

FIG. 5 illustrates a cross-sectional view of the semiconductor memory device taken along a line I-I′ and a line II-II′ shown in FIG. 4.

Referring to FIGS. 4 and 5, each gate stack GST may include a source select line SSL, a plurality of word lines WL1 to WLn, and two or more drain select lines DSL. The plurality of word lines WL1 to WLn may be disposed to be spaced apart from the source select line SSL in the third direction D3. The plurality of word lines WL1 to WLn may be disposed to be spaced apart from each other in the third direction D3. The two or more drain select lines DSL may be disposed to be spaced apart from the plurality of word lines WL1 to WLn in the third direction D3. The two or more drain select lines DSL may be spaced apart from each other with an insulating structure 151 interposed therebetween. The two or more drain select lines DSL may be adjacent to each other in the first direction D1.

Each of the word lines WL1 to WLn may overlap the two or more drain select lines DSL. To this end, the plurality of word lines WL1 to WLn may be formed to have a width wider than that of each of the drain select lines DSL in the first direction D1. As an embodiment, the gate stack GST may include the plurality of word lines WL1 to WLn and first to fourth drain select lines DSL1 to DSL4 overlapping the plurality of word 10 lines WL1 to WLn. The first to fourth drain select lines DSL1 to DSL4 may be disposed to be spaced apart from each other in the first direction D1. Each of the word lines WL1 to WLn may continuously extend in the first direction D1 to overlap the first to fourth drain select lines DSL1 to DSL4.

The insulating structure 151 may be disposed between the first drain select line DSL1 and the second drain select line DSL2 adjacent in the first direction D1, between the second drain select line DSL2 and the third drain select line DSL3 adjacent in the first direction D1, and between the third drain select line DSL3 and the fourth drain select line DSL4 adjacent in the first direction D1. The insulating structure 151 may have a width defined along the first direction D1, a length defined along the second direction D2, and a height defined along the third direction D3.

The source select line SSL may extend in parallel to the plurality of word lines WL1 to WLn (i.e., WL1-WLn). As an embodiment, the source select line SSL may continuously extend in the first direction D1 to overlap the first to fourth drain select lines DSL1 to DSL4.

The plurality of bit lines BL may extend in a direction overlapping the first to fourth drain select lines DSL1 to DSL4. As an embodiment, the plurality of bit lines BL may extend in the first direction D1.

The plurality of cell plugs CP may extend in the third direction D3. The plurality of cell plugs CP may be surrounded by each of the source select line SSL and each of the word lines WL1 to WLn. Each of the first to fourth drain select lines DSL1 to DSL4 may be penetrated by a cell plug CP corresponding thereto. The insulating structure 151 may overlap some of the plurality of cell plugs CP.

The plurality of cell plugs CP may be arranged in a plurality of columns spaced apart from each other in a direction in which the plurality of bit lines BL extend and a plurality of rows spaced apart from each other in a direction crossing the plurality of bit lines BL. As an embodiment, each column of the plurality of cell plugs CP may be configured of cell plugs arranged in a line along the first direction D1, and each row of the plurality of cell plugs CP may be configured of two or more cell plugs arranged in a line along the second direction D2. The plurality of cell plugs CP may be disposed to be spaced apart from each other in the first direction D1 and the second direction D2.

In some embodiments, at least four bit lines BL may overlap each cell plug CP. Accordingly, in an embodiment, even though a distance between the bit lines BL and a width of each bit line BL shown in FIG. 4 are formed narrowly by a process restriction, because a width of a hole for the cell plug CP may be wider than a width by the process restriction, stability of an etching process for forming the hole may be secured. As an embodiment, the cell plug CP may extend in the second direction D2 to overlap by the four bit lines BL.

The number of cell plugs CP passing through each drain select line DSL and arranged in a line in an extension direction of the bit line BL (for example, the first direction D1) may be at least four corresponding to the number of bit lines BL overlapping each cell plug CP. According to an embodiment of the present disclosure, an area allocated to the peripheral circuit structure may be reduced compared to a case where the number of cell plugs CP controlled by the same drain select line DSL and arranged in a line in the first direction D1 is less than the number of bit lines BL overlapping each cell plug CP. For example, when the number of cell plugs CP controlled by the same drain select line DSL and arranged in a line in the first direction D1 is less than the number of bit lines BL overlapping each cell plug CP, an area allocated to the row decoder 33 shown in FIG. 1 for controlling the plurality of drain select lines DSL may be increased compared to an embodiment of the present disclosure. In addition, according to an embodiment of the present disclosure, a connection structure between the cell plug CP and the bit line BL corresponding to the cell plug CP may be simplified compared to a case where the number of cell plugs CP controlled by the same drain select line DSL and arranged in a line in the first direction D1 is greater than the number of bit lines BL overlapping each cell plug CP.

The plurality of contact plugs CT may be connected to the plurality of cell plugs CP, respectively. The plurality of cell plugs CP may be electrically connected to the plurality of bit lines BL by the plurality of contact plugs CT, respectively. As an embodiment, the four cell plugs CP controlled by the same drain select line DSL and arranged in the same column may be respectively connected to the four bit lines BL overlapping each of the four cell plugs CP through the four contact plugs CT. Accordingly, the four cell plugs CP controlled by the same drain select line DSL may be individually controlled through the four bit lines BL.

Referring to FIG. 5, the gate stack GST of the semiconductor memory device may be disposed on the source structure SL. The source structure SL may be formed of a conductive material. The source structure SL may include a doped semiconductor layer of at least one layer including a conductive type of impurity. As an embodiment, the source structure SL may include a first source layer 101, a second source layer 103, and a third source layer 105 stacked in the third direction D3. The first source layer 101 may include a doped semiconductor layer or may include a stack structure of a metal layer and a doped semiconductor layer. The doped semiconductor layer of the first source layer 101 may include at least one of an n-type impurity and a p-type impurity. The second source layer 103 may include an n-type doped semiconductor layer. The third source layer 105 may include an n-type doped semiconductor layer. The third source layer 105 may be omitted, and in this case, a lowest interlayer insulating layer among interlayer insulating layers 111 of the gate stack GST may contact the second source layer 103.

The vertical structure VS may extend in the third direction D3 along a sidewall of the gate stack GST. The vertical structure VS may extend to pass through the third source layer 105. As an embodiment, the vertical structure VS may include a sidewall insulating layer 141 and a conductive source contact structure 143. The conductive source contact structure 143 may be in contact with the second source layer 103 to be electrically connected to the source structure SL. The conductive source contact structure 143 may extend from the second source layer 103 in the third direction D3. The sidewall insulating layer 141 may be disposed between the conductive source contact structure 143 and the gate stack GST to insulate the conductive source contact structure 143 from a plurality of conductive patterns 113. The sidewall insulating layer 141 may extend between the third source layer 105 and the conductive source contact structure 143. Although not shown in the drawing, as an embodiment, the vertical structure VS may be formed of an insulator filling a space between adjacent gate stacks GST.

Each bit line BL may be formed of a conductive material. The bit line BL may be spaced apart from the gate stack GST in the third direction D3 by at least one insulating layer disposed between the bit line BL and the gate stack GST. As an embodiment, a first insulating layer 131 and a second insulating layer 161 may be disposed between the gate stack GST and the bit line BL.

The gate stack GST may include the plurality of interlayer insulating layers 111 and the plurality of conductive patterns 113 alternately stacked in the third direction D3. The plurality of conductive patterns 113 may include a source select line SSL of at least one layer, a plurality of word lines WL1 to WLn, and two or more drain select lines DSL disposed on at least one layer. The source select line SSL may be spaced apart from the source structure SL in the third direction D3. The drain select line DSL may be spaced apart from the source select line SSL in the third direction D3. The plurality of word lines WL1 to WLn may be disposed between the source select line SSL and the drain select line DSL and may be spaced apart from each other in the third direction D3.

The insulating structure 151 may overlap the plurality of word lines WL1 to WLn. The insulating structure 151 may be disposed between the drain select lines DSL adjacent in the first direction D1 as shown in FIG. 4. The insulating structure 151 may extend to pass through the first insulating layer 131.

The plurality of cell plugs CP may pass through the gate stack GST, and may pass through the third source layer 105 and the second source layer 103. The plurality of cell plugs CP may extend into the first source layer 101. The plurality of cell plugs CP may protrude in the third direction D3 further than the gate stack GST. An upper end of the plurality of cell plugs CP protruding further than the gate stack GST may be covered by the first insulating layer 131.

Each cell plug CP may include a channel structure CH, a tunnel insulating layer TI, a data storage layer DS, and a blocking insulating layer BI.

The channel structure CH may pass through the gate stack GST, and may pass through the third source layer 105 and the second source layer 103. The channel structure CH may extend inside the first source layer 101 and inside the first insulating layer 131. The channel structure CH may include a channel layer 121, a core insulating layer 123, and a doped semiconductor layer 125. The core insulating layer 123 and the doped semiconductor layer 125 may be disposed in a central area of the channel structure CH and may be stacked in the third direction D3. The doped semiconductor layer 125 may include a conductivity-type impurity. As an embodiment, the doped semiconductor layer 125 may include an n-type impurity. The channel layer 121 may surround a sidewall of the doped semiconductor layer 125 and may extend to surround a sidewall of the core insulating layer 123. The channel layer 121 may extend along a bottom surface of the core insulating layer 123. The channel layer 121 may be formed of a semiconductor material such as silicon or germanium.

The tunnel insulating layer TI may extend along a sidewall and a bottom surface of the channel structure CH. The data storage layer DS may extend along a sidewall and a bottom surface of the tunnel insulating layer TI. The blocking insulating layer BI may extend along a sidewall and a bottom surface of the data storage layer DS. The data storage layer DS may include a material capable of storing data that is changed using Fowler-Nordheim tunneling. As an embodiment, the data storage layer DS may be formed of a nitride layer capable of charge trapping. An embodiment of the present disclosure is not limited thereto, and the data storage layer DS may be formed of a nano dot, a variable resistance layer, or the like. The blocking insulating layer may include an oxide capable of blocking charge, and the tunnel insulating layer may include a silicon oxide capable of charge tunneling.

The second source layer 103 may pass through the tunnel insulating layer TI, the data storage layer DS, and the blocking insulating layer BI to be in contact with the channel layer 121 of the channel structure CH. Accordingly, the tunnel insulating layer TI, the data storage layer DS, and the blocking insulating layer BI may be separated into a first memory pattern ML1 and a second memory pattern ML2 by the second source layer 103. The first memory pattern ML1 may be disposed between the channel structure CH and the gate stack GST, and may extend between the channel structure CH and the third source layer 105. The second memory pattern ML2 may be disposed between the channel structure CH and the first source layer 101.

The plurality of cell plugs CP may be divided into at least two groups. Each group may include at least four channel structures CH arranged in a line along the first direction D1. The cell plugs CP of each group may include an edge cell plug CP_EG adjacent to the insulating structure 151. The insulating structure 151 may include a portion overlapping the edge cell plug CP_EG. As an embodiment, the channel structure CH of the edge cell plug CP_EG may include a first area AR1 overlapping by the insulating structure 151 in the third direction D3, and a second area AR2 extending toward another cell plug CP from the first area AR1. The channel structure CH of the edge cell plug CP_EG may be formed shorter in the third direction D3 than the second area AR2 in the first area AR1. The channel structure CH of the edge cell plug CP_EG may extend in the third direction D3 along a sidewall of the insulating structure 151 in the second area AR2.

The first insulating layer 131 may be penetrated by the vertical structure VS. The second insulating layer 161 may cover the first insulating layer 131 and the vertical structure VS. The bit line BL may be insulated from the conductive source contact structure 143 by the second insulating layer 161. The bit line BL may be connected to the channel structure CH of the cell plug CP corresponding thereto through the contact plug CT. The contact plug CT may be formed of a conductive material.

A contact structure between the source structure SL and the channel structure CH is not limited to that shown in FIG. 5.

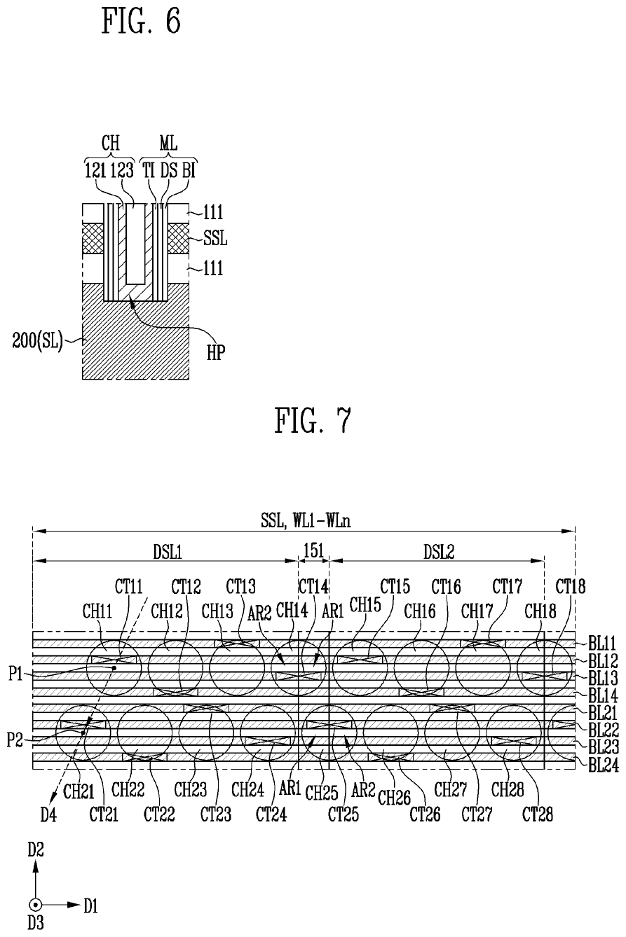

FIG. 6 is a cross-sectional view illustrating a source structure and a channel structure according to an embodiment of the present disclosure. Hereinafter, a repetitive description of the same configuration as that of FIG. 4 is omitted.

Referring to FIG. 6, the source structure SL may include a doped semiconductor layer 200. The doped semiconductor layer 200 may include at least one of an n-type impurity and a p-type impurity.

The channel structure CH may pass through the interlayer insulating layer 111 and the source select line SSL. The channel layer 121 of the channel structure CH may extend along the sidewall and the bottom surface of the core insulating layer 123. A horizontal portion HP of the channel layer 121 extending along the bottom surface of the core insulating layer 123 may contact the doped semiconductor layer 200.

A memory layer ML may include the tunnel insulating layer TI, the data storage layer DS, and the blocking insulating layer BI. Each of the tunnel insulating layer TI, the data storage layer DS, and the blocking insulating layer BI may extend along the sidewall of the channel structure CH.

FIG. 7 is an enlarged plan view of a portion of the semiconductor memory device shown in FIG. 4.

As shown in FIG. 5, the plurality of cell plugs CP shown in FIG. 4 may include the plurality of channel structures CH. The plurality of channel structures CH shown in FIG. 5 may be arranged according to an arrangement rule of the plurality of cell plugs CP described with reference to FIG. 4.

FIG. 7 illustrates first to eighth channel structures CH11 to CH18 of a first column and first to eighth channel structures CH21 to CH28 of a second column among the plurality of channel structures corresponding to the plurality of cell plugs CP shown in FIG. 4.

Referring to FIG. 7, the first to eighth channel structures CH11 to CH18 of the first column may be spaced apart from each other in the first direction D1 and may be arranged in a line. The first to eighth channel structures CH11 to CH18 of the first column may be spaced apart from each other in a substantially constant distance in the first direction D1. The first to eighth channel structures CH21 to CH28 of the second column may be spaced apart from each other in the first direction D1 and may be arranged in a line. The first to eighth channel structures CH21 to CH28 of the second column may be spaced apart from each other in a substantially constant distance in the first direction D1. The first to eighth channel structures CH11 to CH18 of the first column may be spaced apart from the first to eighth channel structures CH21 to CH28 of the second column in the second direction D2 and may be adjacent to the first to eighth channel structures CH21 to CH28 of the second column.

The plurality of bit lines BL shown in FIG. 4 may include first to fourth bit lines BL11 to BL14 of a first group and first to fourth bit lines BL21 to BL24 of a second group. The first to fourth bit lines BL11 to BL14 of the first group may overlap each of the first to eighth channel structures CH11 to CH18 of the first column. The first to fourth bit lines BL11 to BL14 of the first group may be spaced apart from each other in the second direction D2 and may extend in the first direction D1. The first to fourth bit lines BL21 to BL24 of the second group may overlap each of the first to eighth channel structures CH21 to CH28 of the second column. The first to fourth bit lines BL21 to BL24 of the second group may be spaced apart from each other in the second direction D2 and may extend in the first direction D1. The first to fourth bit lines BL11 to BL14 of the first group may be disposed to be spaced apart from the first to fourth bit lines BL21 to BL24 of the second group in the second direction D2.

According to the above-described arrangement, the first to fourth bit lines BL11 to BL14 of the first group might not overlap the first to eighth channel structures CH21 to CH28 of the second column, and the first to fourth bit lines BL21 to BL24 of the second group might not overlap the first to eighth channel structures CH11 to CH18 of the first column.

The first to eighth channel structures CH21 to CH28 of the second column may be disposed at a position displaced in a diagonal direction with respect to the first to fourth bit lines BL11 to BL14 of the first group and the first to fourth bit lines BL21 to BL24 of the second group from the first to eighth channel structures CH11 to CH18 of the first column. For example, a center point P2 of the first channel structure CH21 of the second column may be disposed at a position displaced in the diagonal direction D4 from the center point P1 of the first channel structure CH11 of the first column.

The first to fourth bit lines BL11 to BL14 of the first group and the first to fourth bit lines BL21 to BL24 of the second group may be disposed to be spaced apart from the first drain select line DSL1 and the second drain select line DSL2 in the third direction D3.

The second drain select line DSL2 may be spaced apart from the first drain select line DSL1 in the first direction D1. The first drain select line DSL1 and the second drain select line DSL2 may be electrically separated from each other by the insulating structure 151 disposed therebetween.

The first drain select line DSL1 may be penetrated by the first to fourth channel structures CH11 to CH14 of the first column and the first to fourth channel structures CH21 to CH24 of the second column.

The fifth to eighth channel structures CH15 to CH18 of the first column may be adjacent to the first to fourth channel structures CH11 to CH14 of the first column in the first direction D1, and the fifth to eighth channel structures CH25 to CH28 of the second column may be adjacent to the first to fourth channel structures CH21 to CH24 of the second column in the first direction D1. The second drain select line DSL2 may be penetrated by the fifth to eighth channel structures CH15 to CH18 of the first column and the fifth to eighth channel structures CH25 to CH28 of the second column.

The fourth channel structure CH14 of the first column and the fifth channel structure CH15 of the first column may be adjacent to each other with the insulating structure 151 interposed therebetween. The fourth channel structure CH14 of the first column may include a first area AR1 overlapped by the insulating structure 151 and a second area AR2 extending from the first area AR1 in a direction away from the fifth channel structure CH15 of the first column. The fifth channel structure CH15 of the first column may be spaced apart from the insulating structure 151 in the first direction D1.

The fourth channel structure CH24 of the second column and the fifth channel structure CH25 of the second column may be adjacent to each other with the insulating structure 151 interposed therebetween. The insulating structure 151 may be spaced apart from the fourth channel structure CH24 of the second column in the first direction D1. The fifth channel structure CH25 may include a first area AR1 overlapped by the insulating structure 151 and a second area AR2 extending from the first area AR1 in a direction away from the fourth channel structure CH24 of the second column.

As shown in FIG. 5, the fourth channel structure CH14 of the first column and the fifth channel structure CH25 of the second column may be formed shorter in the third direction D3 than the second area AR2 in the first area AR1. As shown in FIG. 5, the fourth channel structure CH14 of the first column and the fifth channel structure CH25 of the second column may extend along the sidewall of the insulating structure 151 in the second area AR2 in the third direction D3.

The first to eighth channel structures CH11 to CH18 of the first column and the first to eighth channel structures CH21 to CH28 of the second column may extend in the third direction D3 to pass through the source select line SSL and the plurality of word lines WL1 to WLn. Each of the source select line SSL and the plurality of word lines WL1 to WLn may continuously extend in the first direction D1 to surround the first to fourth channel structures CH11 to CH14 of the first column and the first to fourth channel structures CH21 to CH24 of the second column and surround the fifth to eighth channel structures CH15 to CH18 of the first column and the fifth to eighth channel structures CH25 to CH28 of the second column.

The plurality of the contact plugs may include first to eighth contact plugs CT11 to CT18 of a first contact group and first to eighth contact plugs CT21 to CT28 of a second contact group.

The first to fourth channel structures CH11 to CH14 of the first column may be respectively connected to the first to fourth bit lines BL11 to BL14 of the first group through the first to fourth contact plugs CT11 to CT14 of the first contact group. The fifth to eighth channel structures CH15 to CH18 of the first column may be respectively connected to the first to fourth bit lines BL11 to BL14 of the first group through the fifth to eighth contact plugs CT15 to CT18 of the first contact group.

The first to fourth channel structures CH21 to CH24 of the second column may be respectively connected to the first to fourth bit lines BL21 to BL24 of the second group through the first to fourth contact plugs CT21 to CT24 of the second contact group. The fifth to eighth channel structures CH25 to CH28 of the second column may be respectively connected to the first to fourth bit lines BL21 to BL24 of the second group through the fifth to eighth contact plugs CT25 to CT28 of the second contact group.

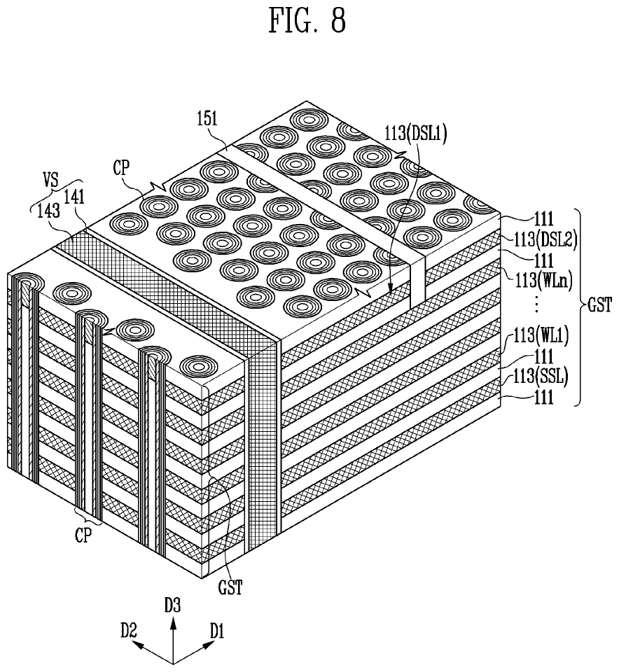

FIG. 8 is a perspective view illustrating a portion of the semiconductor memory device shown in FIG. 4.

Referring to FIG. 8, the gate stacks GST may be disposed on both sides of the vertical structure VS. Each gate stack GST may include a plurality of interlayer insulating layers 111 and a plurality of conductive patterns 113 alternately disposed in the third direction D3. The conductive source contact structure 143 of the vertical structure VS may be electrically separated from the plurality of conductive patterns 113 by the sidewall insulating layer 141.

The plurality of conductive patterns 113 may include the source select line SSL, the plurality of word lines WL1 to WLn, and a first drain select line DSL1 and a second drain select line DSL2 disposed to be spaced apart from the plurality of word lines WL1 to WLn in the third direction D3.

The insulating structure 151 may extend between the first drain select line DSL1 and the second drain select line DSL2 of the gate stack GST. A depth of the insulating structure 151 may be controlled so as not to pass through the source select line SSL and the plurality of word lines WL1 to WLn.

The plurality of cell plugs CP may be spaced apart from each other in the first direction D1 and the second direction D2 in the gate stack GST. Some of the plurality of cell plugs CP may include an area overlapping the insulating structure 151.

Hereinafter, a method of manufacturing a semiconductor memory device according to an embodiment of the present disclosure is described.

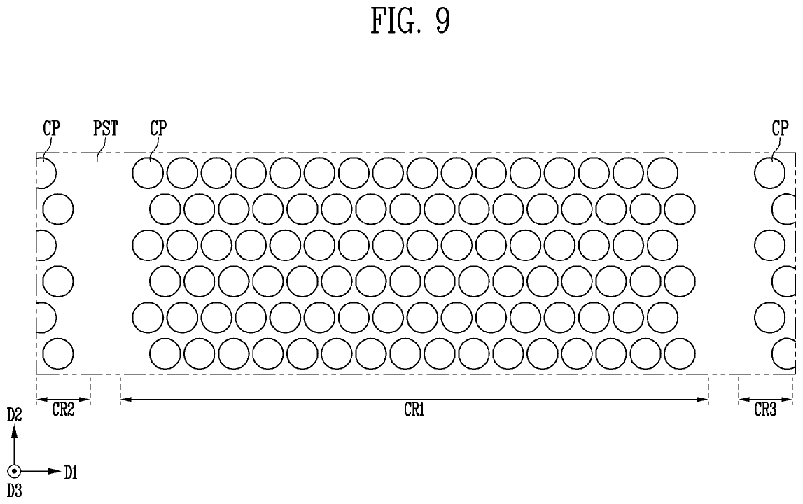

FIG. 9 is a plan view illustrating a method of manufacturing a semiconductor memory device according to an embodiment of the present disclosure.

Referring to FIG. 9, a preliminary stack PST may be formed on a lower structure (not shown) including a substrate, multiple layers, a source structure, a peripheral circuit structure, and the like. The preliminary stack PST may extend in the first direction D1 and the second direction D2 different from each other. The preliminary stack PST may include a plurality of cell array areas spaced apart from each other in the first direction D1. As an embodiment, the preliminary stack PST may include first to third cell array areas CR1 to CR3 spaced apart from each other. The first cell array area CR1 may be disposed between the second cell array area CR2 and the third cell array area CR3. The first cell array area CR1 may be spaced apart from the second cell array area CR2 in the first direction D1, and the third cell array area CR3 may be spaced apart from the first cell array area CR1 in the first direction D1.

Subsequently, the plurality of cell plugs CP passing through the preliminary stack PST may be formed in each of the first to third cell array areas CR1 to CR3. The plurality of cell plugs CP may be arranged to be spaced apart from each other in the first direction D1 and the second direction D2. The plurality of cell plugs CP may pass through the preliminary stack PST according to the arrangement rule described with reference to FIGS. 4 and 5.

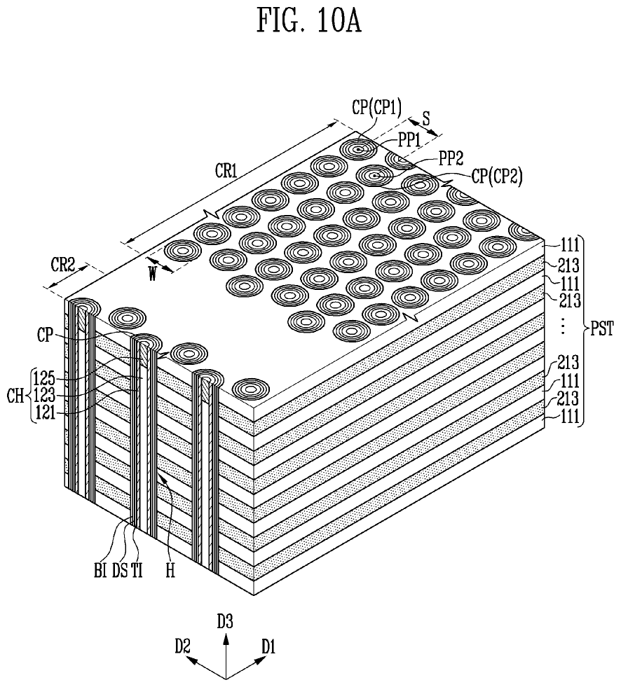

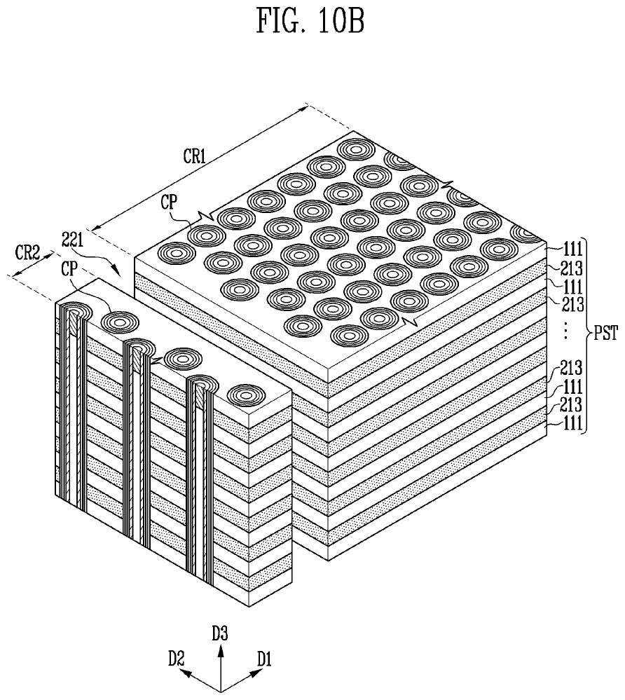

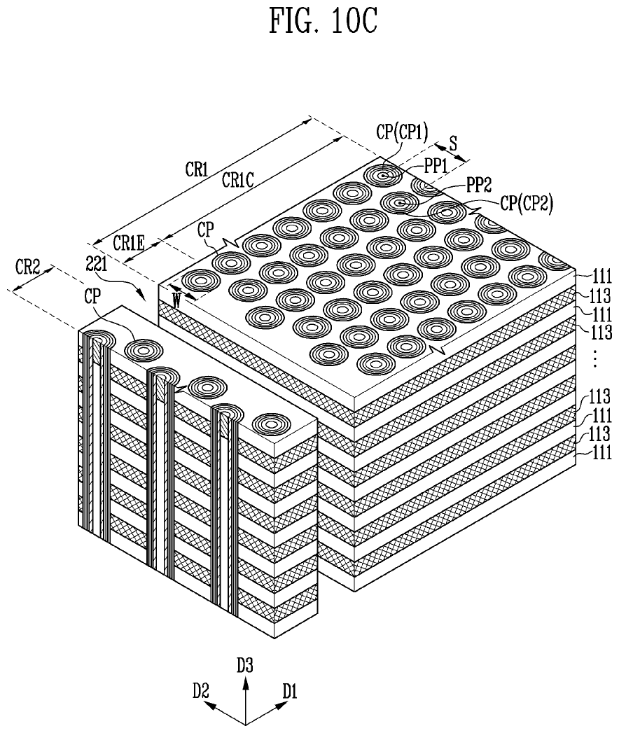

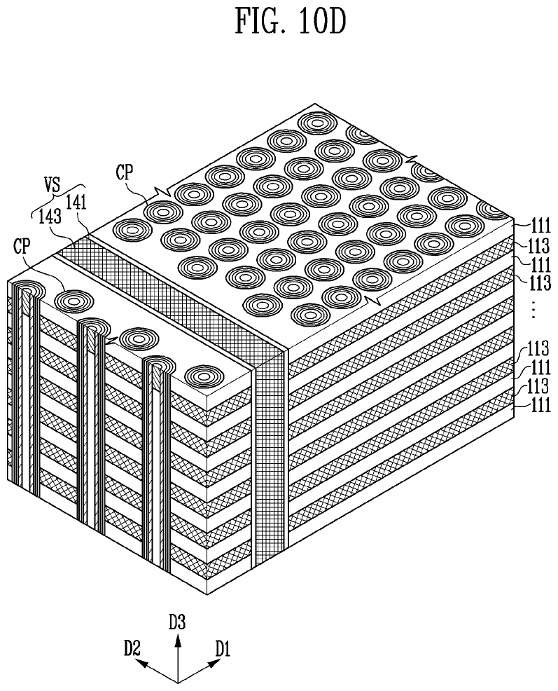

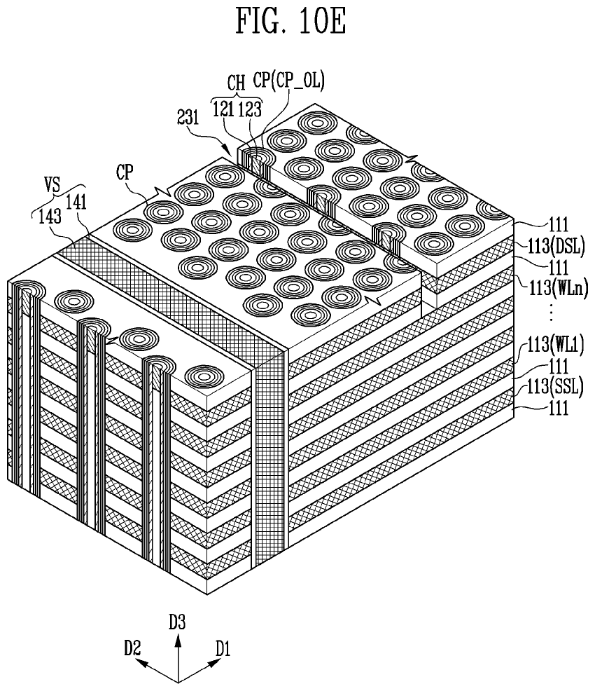

FIGS. 10A to 10E are perspective views illustrating a method of manufacturing a semiconductor memory device according to an embodiment of the present disclosure.

FIG. 10A is a perspective view illustrating a portion of the preliminary stack PST shown in FIG. 9.

Referring to FIG. 10A, the preliminary stack PST may include a plurality of first material layers and a plurality of second material layers that are alternately stacked in the third direction D3. The plurality of second material layers may be formed of a material having an etch selectivity with respect to the plurality of first material layers. As an embodiment, the plurality of first material layers may serve as a plurality of interlayer insulating layers 111, and the plurality of second material layers may serve as a plurality of sacrificial layers 213.

The plurality of sacrificial layers 213 may have an etch selectivity greater than 1 with respect to the plurality of interlayer insulating layers 111. For example, the plurality of interlayer insulating layers 111 may be formed of an oxide such as silicon oxide, and the plurality of sacrificial layers 213 may be formed of a nitride such as silicon nitride. An embodiment of the present disclosure is not limited thereto. For example, the plurality of first material layers may serve as the plurality of interlayer insulating layers 111, and the plurality of second material layers may serve as a plurality of conductive layers for conductive patterns. Each of the conductive layers may include at least one of doped silicon, a metal layer, and a metal silicide layer.

In each of the cell array areas CR1 and CR2, the preliminary stack PST may be penetrated by the plurality of cell plugs CP. Each cell plug CP may include the blocking insulating layer BI, the data storage layer DS, the tunnel insulating layer TI, and the channel structure CH, as described with reference to FIG. 5. As described with reference to FIG. 5, the channel structure CH may include the channel layer 121, the core insulating layer 123, and the doped semiconductor layer 125.

Forming the plurality of cell plugs CP may include forming a plurality of holes H passing through the preliminary stack PST in each of the cell array areas CR1 and CR2, forming the blocking insulating layer BI along a sidewall of each hole H, forming the data storage layer DS along the blocking insulating layer BI, forming the tunnel insulating layer TI along the data storage layer DS, and forming the channel layer 121 along the tunnel insulating layer TI. When a central area of the hole H is opened without being filled with the channel layer 121, the core insulating layer 121 may be formed in the central area of the hole H. Subsequently, a portion of the core insulating layer 121 may be removed to form a recess area opening a portion of the central area of the hole H. Thereafter, the doped semiconductor layer 125 may be formed in the recess area. A conductive-type impurity in the doped semiconductor layer 125 may be diffused into a partial area of the channel layer 121 surrounding the doped semiconductor layer 125.

The plurality of cell plugs CP may be disposed in a plurality of columns spaced apart from each other in the second direction D2. For example, the plurality of cell plugs CP may include a plurality of first cell plugs CP1 of the first column arranged in a line in the first direction D1 and a plurality of second cell plugs CP2 of the second column arranged in a line in the first direction D1. The plurality of first cell plugs CP1 of the first column may be spaced apart from the plurality of second cell plugs CP2 of the second column in the second direction D2. For example, a separation distance S in the second direction D2 between center points PP1 and PP2 of the first cell plug CP1 and the second cell plug CP2 adjacent to each other may be defined to be greater than a width W in the second direction D2.

FIGS. 10B and 10C illustrates an embodiment of subsequent processes following the process shown in FIG. 10A.

Referring to FIG. 10B, a slit 221 passing through the preliminary stack PST may be formed between cell array areas (for example, CR1 and CR2) adjacent in the first direction D1.

Referring to FIG. 10C, a replacement process of replacing the plurality of sacrificial layers 213 shown in FIG. 10B with the plurality of conductive patterns 113 may be performed through the slit 221. As shown in FIG. 10A, the separation distance S in the second direction D2 between the center point PP1 of the first cell plug CP1 and the center point PP2 of the second cell plug CP2 may be defined to be greater than the width W of each cell plug CP in the second direction D2. Accordingly, while performing the replacement process, the sacrificial layer 213 shown in FIG. 10B may be removed through a space between the cell plugs CP adjacent in the second direction D2. In addition, while performing the replacement process, the conductive pattern 113 may be input to a center portion (for example, CR1C) of each cell array area through the space between the cell plugs CP adjacent in the second direction D2. The center portion CR1C of the cell array area may be defined as an area disposed at a position more distant from the slit 221 than an edge portion CR1E of the cell array area.

When the second material layer described with reference to FIG. 10A is formed of a conductive layer for a conductive pattern, the above-described replacement process may be omitted.

FIG. 10D is a diagram illustrating an embodiment of a subsequent process after the interlayer insulating layers 111 and the conductive patterns 113 penetrated by the slit 221 and alternately disposed in the third direction D3 are provided.

Referring to FIG. 10D, the vertical structure VS may be formed inside the slit 221 shown in FIG. 10C. As an embodiment, forming the vertical structure VS may include forming the sidewall insulating layer 143 on a sidewall of the slit 221 shown in FIG. 10C and forming the conductive source contact structure 143 inside the slit 221 opened by the sidewall insulating layer 143.

FIG. 10E is a diagram illustrating an embodiment of a process of separating some of the plurality of conductive patterns 113 into the plurality of drain select lines DSL.

Referring to FIG. 10E, a trench 231 passing through a conductive pattern of at least one layer disposed on an uppermost layer among the plurality of conductive patterns 113 may be formed. The trench 231 may overlap some (for example, CP_OL) of the plurality of cell plugs CP. A portion of the channel structure CH in the cell plug CP_OL overlapping the trench 231 may be removed while forming the trench 231.

The drain select lines DSL spaced apart in the first direction D1 may be defined by the above-described trench 231. The conductive patterns 113 under the drain select lines DSL might not pass through the trench 231 and may be defined as the plurality of word lines WL1 to WLn and the source select line SSL.

Subsequently, the trench 231 may be filled with the insulating structure 151 shown in FIG. 8. Thereafter, subsequent processes for forming the plurality of contact plugs CT and the plurality of bit lines BL shown in FIG. 5 may be performed.

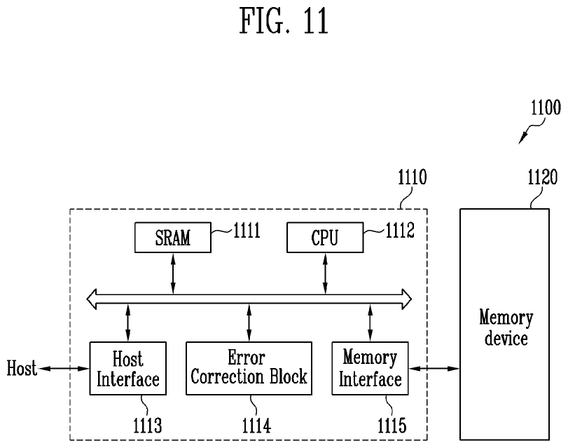

FIG. 11 is a block diagram illustrating a configuration of a memory system according to an embodiment of the present disclosure.

Referring to FIG. 11, the memory system 1100 includes a memory device 1120 and a memory controller 1110.

The memory device 1120 may be a multi-chip package configured of a plurality of flash memory chips. In an embodiment, the memory device 1120 may include a drain select line spaced apart from a source structure, first to fourth bit lines of a first group spaced apart from the drain select line, first to fourth channel structures of a first column extending from the source structure to pass through the drain select line, and first to fourth contact plugs of the first contact group connecting the first to fourth channel structures of the first column to the first to fourth bit lines of the first group, respectively. Each of the first to fourth channel structures of the first column may extend to overlap the first to fourth bit lines of the first group.

The memory controller 1110 may be configured to control the memory device 1120, and may include a static random access memory (SRAM) 1111, a central processing unit (CPU) 1112, a host interface 1113, an error correction block 1114, and a memory interface 1115. The SRAM 1111 is used as an operation memory of the CPU 1112, the CPU 1112 performs an overall control operation for data exchange of the memory controller 1110, and the host interface 1113 includes a data exchange protocol of a host connected to the memory system 1100. The error correction block 1114 detects an error included in data read from the memory device 1120 and corrects the detected error. The memory interface 1115 performs interfacing with the memory device 1120. The memory controller 1110 may further include a read only memory (ROM) that stores code data for interfacing with the host.

The above-described memory system 1100 may be a memory card or a solid state drive (SSD) in which the memory device 1120 and the memory controller 1110 are combined. For example, when the memory system 1100 is the SSD, the memory controller 1110 may communicate with the outside (for example, the host) through one of various interface protocols such as a universal serial bus (USB), a multimedia card (MMC), a peripheral component interconnection-express (PCI-E), a serial advanced technology attachment (SATA), a parallel advanced technology attachment (PATA), a small computer system interface (SCSI), an enhanced small disk interface (ESDI), and integrated drive electronics (IDE).

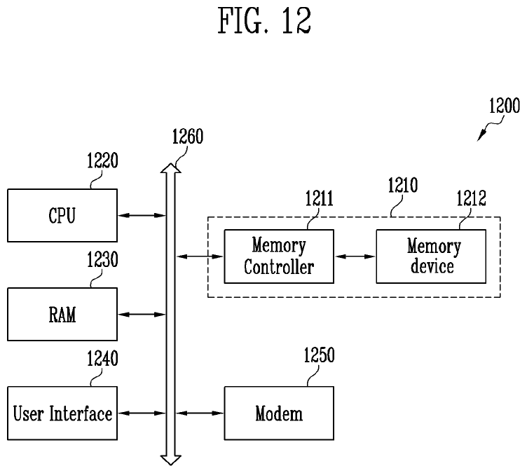

FIG. 12 is a block diagram illustrating a configuration of a computing system according to an embodiment of the present disclosure.

Referring to FIG. 12, the computing system 1200 may include a CPU 1220, a random access memory (RAM) 1230, a user interface 1240, a modem 1250, and a memory system 1210 electrically connected to a system bus 1260. When the computing system 1200 is a mobile device, a battery for supplying an operation voltage to the computing system 1200 may be further included, and an application chipset, an image processor, a mobile DRAM, and the like may be further included.

The memory system 1210 may include a memory device 1212 and a memory controller 1211.

In an embodiment, the memory device 1212 may include a drain select line spaced apart from a source structure, first to fourth bit lines of a first group spaced apart from the drain select line, first to fourth channel structures of a first column extending from the source structure to pass through the drain select line, and first to fourth contact plugs of the first contact group connecting the first to fourth channel structures of the first column to the first to fourth bit lines of the first group, respectively. Each of the first to fourth channel structures of the first column may extend to overlap the first to fourth bit lines of the first group.

According to an embodiment of the present disclosure, stability of a channel structure forming process may be improved by controlling a width of a channel structure to overlap at least four bit lines. Accordingly, in an embodiment, stability of a manufacturing process of the semiconductor memory device may be improved.

What is claimed is:

1. A semiconductor memory device comprising:
a source structure having a surface extending in a first direction and a second direction different from the first direction;
a first drain select line spaced apart from the source structure in a third direction, the third direction crossing the surface of the source structure;
a first group of bit lines including first, second, third, and fourth bit lines, wherein the first group of bit lines is spaced apart from the first drain select line in the third direction, wherein the first to fourth bit lines of the first group of bit lines extend in the first direction, and wherein the first to fourth bit lines of the first group of bit lines are spaced apart from each other in the second direction;
a first column of channel structures including first, second, third, and fourth channel structures, wherein the first to fourth channel structures of the first column of channel structures are spaced apart from each other in the first direction, and wherein the first to fourth channel structures of the first column of channel structures, each extend from the source structure in the third direction to pass through the first drain select line;
a first contact group of contact plugs including first, second, third, and fourth contact plugs, wherein the first to fourth contact plugs of the first contact group of contact plugs connect the first to fourth channel structures of the first column of channel structures to the first to fourth bit lines of the first group of bit lines, respectively; and
a word line disposed between the first drain select line and the source structure and surrounding the first to fourth channel structures of the first column of channel structures,
wherein each of the first to fourth channel structures of the first column of channel structures extend in the second direction to overlap the first to fourth bit lines of the first group of bit lines.

2. The semiconductor memory device of claim 1, further comprising:
a second column of channel structures including first, second, third, and fourth channel structures, wherein the first to fourth channel structures of the second column of channel structures are disposed at a position displaced in a diagonal direction with respect to the first to fourth bit lines of the first group of bit lines from the first to fourth channel structures of the first column of channel structures, and wherein the first to fourth channel structures of the second column of channel structures each extend in the third direction from the source structure to pass through the first drain select line;
a second group of bit lines including first, second, third, and fourth bit lines, wherein the first to fourth bit lines of the second group of bit lines overlap each of the first to fourth channel structures of the second column of channel structures, wherein the first to fourth bit lines of the second group of bit lines extend in the first direction, and wherein the first to fourth bit lines of the second group of bit lines are spaced apart from each other in the second direction; and
a second contact group of contact plugs including first, second, third, and fourth contact plugs, wherein the first to fourth contact plugs of the second contact group of contact plugs connect the first to fourth channel structures of the second column of channel structures to the first to fourth bit lines of the second group of bit lines, respectively.

3. The semiconductor memory device of claim 2, wherein the first to fourth channel structures of the first column of channel structures are spaced apart from the first to fourth channel structures of the second column of channel structures in the second direction.

4. The semiconductor memory device of claim 2, wherein the first to fourth bit lines of the first group of bit lines do not overlap the first to fourth channel structures of the second column of channel structures, and
the first to fourth bit lines of the second group of bit lines do not overlap the first to fourth channel structures of the first column of channel structures.

5. The semiconductor memory device of claim 1, further comprising:
a second drain select line spaced apart from the first drain select line in the first direction;
fifth, sixth, seventh, and eighth channel structures of the first column of channel structures adjacent to the first to fourth channel structures of the first column of channel structures in the first direction and the fifth to eighth channel structures of the first column of channel structures each extending from the source structure in the third direction to pass through the second drain select line; and
fifth, sixth, seventh, and eighth contact plugs of the first contact group of contact plugs connecting the fifth to eighth channel structures of the first column of channel structures to the first to fourth bit lines of the first group of bit lines, respectively.

6. The semiconductor memory device of claim 5, wherein the word line continuously extends in the first direction to surround fifth to eighth channel structures of the first column of channel structures.

7. The semiconductor memory device of claim 5, further comprising:
an insulating structure disposed between the first drain select line and the second drain select line.

8. The semiconductor memory device of claim 7, wherein the fourth channel structure of the first column of channel structures and the fifth channel structure of the first column of channel structures are adjacent to each other with the insulating structure interposed therebetween,
the fifth channel structure of the first column of channel structures is spaced apart from the insulating structure in the first direction, and
the fourth channel structure of the first column of channel structures includes a first area overlapping the insulating structure and a second area extending from the first area in a direction away from the fifth channel structure of the first column of channel structures.

9. The semiconductor memory device of claim 8, wherein the fourth channel structure of the first column of channel structures is formed shorter than the second area in the first area in the third direction, and
the fourth channel structure of the first column of channel structures extends in the third direction along a sidewall of the insulating structure in the second area.

10. A semiconductor memory device comprising:
a source structure having a surface extending in a first direction and a second direction different from the first direction;
a word line disposed to be spaced apart from the source structure in a third direction crossing the surface of the source structure;
an insulating structure overlapping the word line, the insulating structure extending in the second direction;
a first drain select line and a second drain select line spaced apart from the word line in the third direction and spaced apart from each other in the first direction with the insulating structure interposed therebetween;
a first column of channel structures including first, second, third, fourth, fifth, sixth, seventh, and eighth channel structures, wherein the first to eighth channel structures of the first column of channel structures are spaced apart from each other along the first direction, wherein each of the first to eighth channel structures of the first column of channel structures extend from the source structure in the third direction, wherein each of the first to fourth channel structures of the first column of channel structures pass through the word line and the first drain select line, and wherein each of the fifth to eighth channel structures of the first column of channel structures pass through the word line and the second drain select line;
a first group of bit lines including first, second, third, and fourth bit lines, wherein the first to fourth bit lines of the first group of bit lines are spaced apart from each other in the second direction, and wherein the first to fourth bit lines of the first group of bit lines extend in the first direction to overlap the first to eighth channel structures of the first column; and
a first contact group of contact plugs including first, second, third, fourth, fifth, sixth, seventh, and eighth contact plugs, wherein the first to fourth contact plugs of the first contact group of contact plugs connect the first to fourth channel structures of the first column of channel structures to the first to fourth bit lines of the first group of bit lines, respectively, and wherein the fifth to eighth contact plugs of the first contact group of contact plugs connect the fifth to eighth channel structures of the first column of channel structures to the first to fourth bit lines of the first group of bit lines, respectively.

11. The semiconductor memory device of claim 10, further comprising:
a second column of channel structures including first, second, third, fourth, fifth, sixth, seventh, and eighth channel structures, wherein each of the first to eighth channel structures of the second column of channel structures extend from the source structure in the third direction, wherein the first to fourth channel structures of the second column of channel structures are disposed at a position displaced in a diagonal direction with respect to the first to fourth bit lines of the first group of bit lines from the first to fourth channel structures of the first column of channel structures, wherein each of the first to fourth channel structures of the second column of channel structures pass through the word line and the first drain select line, wherein the fifth to eighth channel structures of the second column of channel structures are disposed at a position displaced in a diagonal direction with respect to the first to fourth bit lines of the first group of bit lines from the fifth to eighth channel structures of the first column of channel structures, and wherein each of the fifth to eighth channel structures of the second column of channel structures pass through the word line and the second drain select line; and
a second group bit lines including first, second, third, and fourth bit lines, wherein the first to fourth bit lines of the second group of bit lines are spaced apart from each other in the second direction, wherein the first to fourth bit lines of the second group of bit lines extend in the first direction to overlap the first to fourth channel structures of the second column of channel structures and to overlap the fifth to eighth channel structures of the second column of channel structures.

12. The semiconductor memory device of claim 11, wherein the first to fourth channel structures of the first column of channel structures are spaced apart from the first to fourth channel structures of the second column of channel structures in the second direction, and
the fifth to eighth channel structures of the first column of channel structures are spaced apart from the fifth to eighth channel structures of the second column of channel structures in the second direction.

13. The semiconductor memory device of claim 11, wherein the fourth channel structure of the first column of channel structures and the fifth channel structure of the first column of channel structures are adjacent to each other with the insulating structure interposed therebetween,
the fourth channel structure of the second column of channel structures and the fifth channel structure of the second column of channel structures are adjacent to each other with the insulating structure interposed therebetween,
the fifth channel structure of the first column of channel structures is spaced apart from the insulating structure in the first direction,
the insulating structure is spaced apart from the fourth channel structure of the second column of channel structures in the first direction, and
each of the fourth channel structure of the first column of channel structures and the fifth channel structure of the second column of channel structures includes a first area overlapped by the insulating structure and a second area extending from the first area.

14. The semiconductor memory device of claim 13, wherein each of the fourth channel structure of the first column of channel structures and the fifth channel structure of the second column of channel structures is formed shorter than the second area in the first area in the third direction, and
each of the fourth channel structure of the first column of channel structures and the fifth channel structure of the second column of channel structures extends in the third direction along a sidewall of the insulating structure in the second area.

15. The semiconductor memory device of claim 11, wherein the first to fourth bit lines of the first group of bit lines do not overlap the first to fourth channel structures of the second column of channels structures and the fifth to eighth channel structures of the second column of channel structures, and
the first to fourth bit lines of the second group of bit lines do not overlap the first to fourth channel structures of the first column of channel structures and the fifth to eighth channel structures of the first column of channel structures.
